(19) United States
(12) Patent Application Publication
(10) Pub. No.: US 2026/0255851 A1
(43) Pub. Date: Aug. 27, 2026

(54) DISPLAY DEVICE

(71) Applicant: LG Display Co., Ltd., Seoul (KR)

(72) Inventors: Soobin LEE, Seoul (KR); Jongmoo HA, Gimpo-si (KR)

(73) Assignee: LG Display Co., Ltd., Seoul (KR)

(21) Appl. No.: 19/432,508

(22) Filed: Dec. 24, 2025

(30) Foreign Application Priority Data
Feb. 21, 2025 (KR) 10-2025-0022949

(51) Int. Cl. H10K 59/80; H10K 59/121; H10K 59/88

(52) U.S. Cl. CPC H10K 59/873; H10K 59/1213; H10K 59/88

(57) ABSTRACT

Discussed is a display device including a display panel including a display area and a non-display area surrounding the display area, a plurality of sub-pixels disposed in the display area, a first area included in the non-display area and surrounding at least three sides of the display area in a plan view of the display device, a second area included in the non-display area and disposed in a position different from a position of the first area, a bendable area included in the non-display area, a first-sized barrier structure disposed in the first area, and a further first-sized barrier structure and a second-sized barrier structure disposed in the second area and spaced apart from each other. The first-sized barrier structure and the second-sized barrier structure have different sizes in the plan view of the display device.

### CROSS-REFERENCE TO RELATED APPLICATION

The present application claims priority to Korean Patent Application No. 10-2025-0022949, filed in the Republic of Korea on February 21, 2025, the entire contents of which is hereby expressly incorporated by reference into the present application.

### BACKGROUND

### Field

The present disclosure relates to a display device.

### Description of the Related Art

A display device is applied to various electronic devices such as a TV, a smartphone, a laptop computer, and a tablet. To this end, research for thinness, light-weightness, low power consumption, and the like of the display device is continuing in order to produce display devices with desired characteristics.

Examples of the display device can include a liquid crystal display (LCD) device, a field emission display (FED) device, an organic light emitting display (OLED) device, and the like among others.

A bezel area of the display device can be visually recognized by a user and can be a factor that degrades a sense of immersion in an image emitted from a display area of the display device. Accordingly, there is an increasing demand for a display device implementing a narrow bezel that reduces the bezel area in which a screen is not displayed while expanding the display area or implementing a zero bezel that substantially has an effect of not having the bezel area for the display device.

In addition, as a demand for and use of a wearable device, especially a smart watch phone, increases, research on applying the organic light emitting display (OLED) device to the smart watch phone is also increasing to produce a reduced bezel or zero bezel smart watch.

### SUMMARY OF THE DISCLOSURE

A purpose of an embodiment of the present disclosure is to provide a display device that can prevent a deterioration or a change in element characteristics of a driving transistor including an oxide semiconductor.

In addition, a purpose of an embodiment of the present disclosure is to provide a display device having a minimized bezel area while placing barrier structures for preventing a change in element characteristics of a driving transistor including an oxide semiconductor.

In addition, a purpose of an embodiment of the present disclosure is to provide a display device that can reduce a defect rate of the display device by maintaining element stability of a driving transistor.

In addition, a purpose of an embodiment of the present disclosure is to provide a display device that can reduce greenhouse gas emission by preventing an increase in production energy required for additional production of the display device.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to an embodiment of the present disclosure includes a display panel including a display area and a non-display area surrounding the display area; a plurality of sub-pixels disposed in the display area; a first area included in the non-display area and surrounding three sides of the display area in a plan view of the display device; a second area included in the non-display area and disposed in a position different from a position of the first area; a bendable area included in the non-display area; a first-sized barrier structure disposed in the first area; and a further first-sized barrier structure and a second-sized barrier structure disposed in the second area and spaced apart from each other, wherein the first-sized barrier structure and the second-sized barrier structure have different sizes in the plan view.

The display device according to an embodiment of the present disclosure can prevent the deterioration or the change in the element characteristics of the driving transistor including the oxide semiconductor by placing the plurality of barrier structures on the bezel area defined outward of the display area.

In addition, the display device according to an embodiment of the present disclosure can minimize the bezel area while placing the multiple barrier structures to prevent the change in the element characteristics of the driving transistor.

Accordingly, the display device according to an embodiment of the present disclosure can maintain the operational stability of the driving transistor including the oxide semiconductor. As a result, the display device according to an embodiment of the present disclosure can prevent the bright spot defect from occurring at the outer portion of the display panel.

As the defect rate is lowered such that the production energy required for the additional production of the display device can be reduced, the display device according to an embodiment of the present disclosure can reduce the greenhouse gas emission.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE DRAWINGS

FIG. 1 is a plan view of a display panel according to an embodiment of the present disclosure.

FIG. 2 is a diagram showing a wearable display device including a display panel according to an embodiment of the present disclosure.

FIG. 3 is a cross-sectional view taken along a line I-I' in FIG. 1.

FIGS. 4 to 6 are diagrams showing threshold voltage values measured based on locations on a display panel.

FIG. 7 is an enlarged view of an area 'II' in FIG. 1.

FIG. 8 is a cross-sectional view taken along a line VI-VI' in FIG. 7.

FIG. 9 is an enlarged view of an area 'III' in FIG. 1.

FIG. 10 is an enlarged view of an area 'IV' in FIG. 1.

FIG. 11 is an enlarged view of an area 'V' in FIG. 1.

FIG. 12 is a cross-sectional view taken along a line VII-VII' in FIG. 11.

### DETAILED DESCRIPTION OF THE EMBODIMENTS

Advantages and Advantages and features of the present disclosure, and a method of achieving the advantages and features will become apparent with reference to embodiments described later in detail together with the accompanying drawings. However, the present disclosure is not limited to the embodiments as disclosed below, but can be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this disclosure, specify the presence of the stated features, integers, operations, elements, and/or components, but do not preclude the presence or addition of one or more other features, integers, operations, elements, components, and/or portions thereof. As used herein, the term "and/or" includes any and all combinations of one or more of associated listed items. Expression such as "at least one of" when preceding a list of elements can modify the entire list of elements and need not modify the individual elements of the list. In interpretation of numerical values, an error or tolerance therein can occur even when there is no explicit description thereof.

In addition, it will also be understood that when a first element or layer is referred to as being present "on" a second element or layer, the first element can be disposed directly on the second element or can be disposed indirectly on the second element with a third element or layer being disposed between the first and second elements or layers. It will be understood that when an element or layer is referred to as being "connected to", or "coupled to" another element or layer, it can be directly connected to, or coupled to the other element or layer, or one or more intervening elements or layers can be present therebetween. In addition, it will also be understood that when an element or layer is referred to as being "between" two elements or layers, it can be the only element or layer between the two elements or layers, or one or more intervening elements or layers can also be present.

Further, as used herein, when a layer, film, area, plate, or the like is disposed "on" or "on top" of another layer, film, area, plate, or the like, the former can directly contact the latter or still another layer, film, area, plate, or the like can be disposed between the former and the latter. As used herein, when a layer, film, area, plate, or the like is directly disposed "on" or "on top" of another layer, film, area, plate, or the like, the former directly contacts the latter and still another layer, film, area, plate, or the like is not disposed between the former and the latter. Further, as used herein, when a layer, film, area, plate, or the like is disposed "beneath" or “under” another layer, film, area, plate, or the like, the former can directly contact the latter or still another layer, film, area, plate, or the like can be disposed between the former and the latter. As used herein, when a layer, film, area, plate, or the like is directly disposed "beneath" or "under" another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms "first", "second", "third", and so on can be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term 'or' means 'inclusive or' rather than 'exclusive or'. For example, unless otherwise stated or clear from the context, the expression that 'x uses a or b' means one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B via another node unless a phrase 'immediately transferred' or 'directly transferred' is used.

Throughout the present disclosure, "A and/or B" means A, B, or A and B, unless otherwise specified, and "C to D" means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure can work functionally.

The term "can" fully encompasses all the meanings and coverages of the term "may." The term “made of” for an element can fully encompass the meaning of being completely formed of the element, or simply including the element.

Hereinafter, a display device according to embodiments of the present disclosure will be described with reference to the drawings.

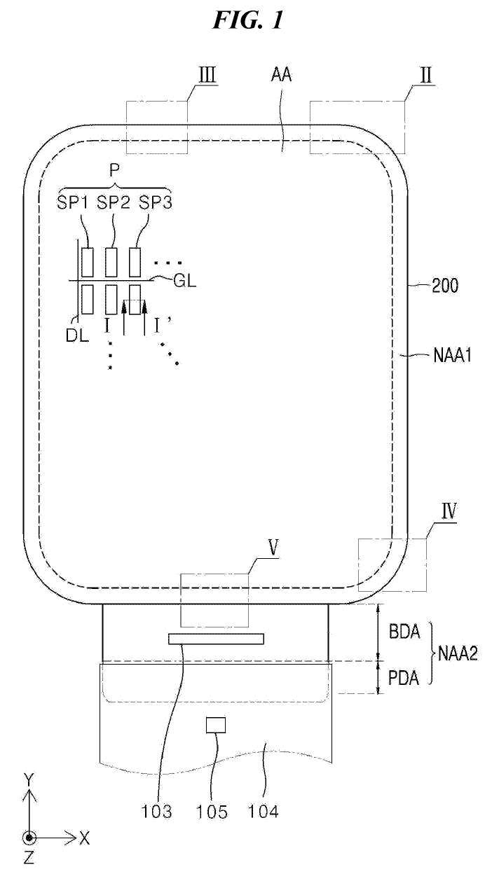

FIG. 1 is a plan view of a display panel according to an embodiment of the present disclosure.

Referring to FIG. 1, a display device according to an embodiment of the present disclosure can include a display panel 200, a printed circuit board 104, a driving circuit chip 103, a control circuit chip 105, and the like. All components of each display panel and display device according to all embodiments of the present disclosure are operatively coupled and configured.

A shape of the display panel 200 can be changed as needed. For example, the display panel 200 can include a quadrangular shape with gently rounded corners, a quadrangular shape, a circular shape, or an oval shape. The display panel 200 can include a display area (or active area) AA and a non-display area (or non-active area) NAA1 and NAA2. The display area AA of the display panel 200 can be an area where an image is displayed, and can have a plurality of pixels P, data lines DL, and gate lines GL disposed thereon.

The non-display area NAA1 and NAA2 can be an area where the image is not displayed. The non-display area NAA1 and NAA2 can include a first non-display area NAA1 and a second non-display area NAA2. The first non-display area NAA1 can be located in a peripheral area (or an edge area) of the display panel 200, but need not be limited thereto. For example, an area other than a light emissive area that emits light to the outside on the display area AA can be referred to as the first non-display area NAA1.

A bezel area of the display device can be defined by the first non-display area NAA1. The bezel area can surround an outer side of the display area AA. For example, the bezel area can refer to the first non-display area NAA1 surrounding an edge of the display panel 200.

The second non-display area NAA2 can be located downward of the display panel 200. The second non-display area NAA2 can include a bendable area BDA and a pad area PDA. The pad area PDA can include a plurality of pads electrically connected to a printed circuit board 104 on which the control circuit chip 105 or the like is disposed.

The driving circuit chip 103 can transmit data signals, touch signals, or the like to the plurality of pixels on the display area AA via the plurality of data lines DL or touch lines. For example, the driving circuit chip 103 can be a data driving circuit chip, but need not be limited thereto.

Lines for providing electrical signals to the display area AA or receiving the electrical signals from the display area AA can be disposed on the non-display area NAA1 and NAA2. For example, a gate driver that supplies gate signals to a plurality of sub-pixels SP1, SP2, and SP3 of the display area AA can be disposed on the first non-display area NAA1. The gate drivers can be arranged at right and left edges of the first non-display area NAA1 in a gate in panel (GIP) manner. The gate driver can transmit the gate signals via the gate lines GL.

The gate lines GL can extend in a first direction (X) of the display panel 200, and the data lines DL can intersect the gate lines GL and extend in a second direction (Y) of the display panel 200.

The display panel 200 can be made of a flexible material. Accordingly, a portion of the second non-display area NAA2 of the display panel 200 can be bent such that the printed circuit board 104 on which the control circuit chip 105 is disposed faces a rear surface of the display area AA of the display panel 200. Accordingly, a size of the second non-display area NAA2 at a lower side recognized from the front of a display device 1 is reduced, so that a portion of the bezel area in a lower portion of the display panel 200 can be further reduced. The control circuit chip 105 can control the driving circuit chip 103 and the gate driver.

A plurality of pixels are on the display area AA. One pixel P on the display area AA can be composed of the plurality of sub-pixels SP1, SP2, and SP3. The image can be displayed in the display area AA via the plurality of sub-pixels SP1, SP2, and SP3. The plurality of sub-pixels SP1, SP2, and SP3 can be arranged in an array on the display area AA. In an example, the plurality of sub-pixels SP1, SP2, and SP3 can be arranged in a matrix manner by being spaced apart from each other in the first direction and the second direction intersecting the first direction of the display area AA. The first direction can be a horizontal direction, an X-axis direction, or a row direction, and the second direction can be a vertical direction, a Y-axis direction, or a column direction. However, the present disclosure need not be limited thereto, and an arrangement shape, an arrangement order, and an arrangement direction of the sub-pixels SP1, SP2, and SP3 can be variously changed.

It is described in the present disclosure that one pixel P is composed of a first sub-pixel SP1, a second sub-pixel SP2, and a third sub-pixel SP3 as an embodiment, but the present disclosure is not limited thereto. For example, one pixel P can further include additional sub-pixels.

The sub-pixels SP1, SP2, and SP3 can be implemented to emit light of the same color, such as white light, or can be implemented to emit light of different colors, such as red, green, or blue light. For example, the first sub-pixel SP1 can render red, the second sub-pixel SP2 can render green, and the third sub-pixel SP3 can render blue.

According to an embodiment of the present disclosure, when the display panel 200 includes the quadrangular shape with gently rounded corners, the display panel 200 can include an upper portion, a right side portion, a lower portion and a left side portion located in a clockwise direction of the display panel 200 in the plan view. The display panel can also include a first corner, a second corner, a third corner and a fourth corner in the clockwise direction of the display panel in the plan view starting from the upper portion. According to these designations, the first corner can be a transition from the upper portion to the right side portion, the second corner can be a transition from the right side portion to the lower portion, the third corner can be a transition from the lower portion to the left side portion, and the fourth corner can be a transition from the left side portion to the upper portion in the clock wise direction around a periphery of the display panel 200. In other embodiments of the present disclosure, when the display panel 200 is of a different shape, the number of portions and corners can vary.

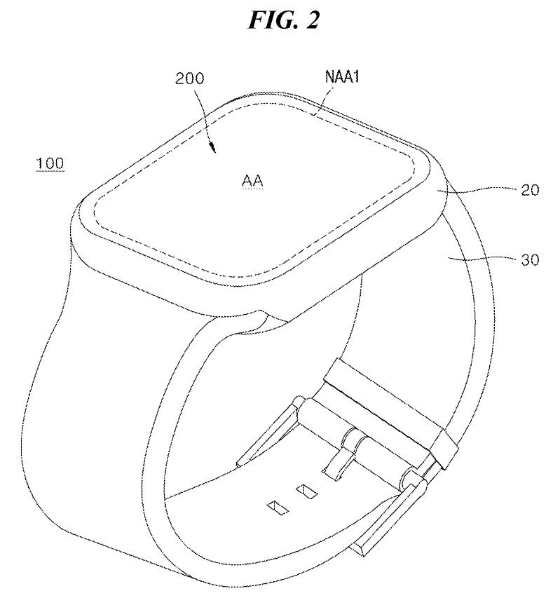

FIG. 2 is a diagram showing a wearable display device including a display panel according to an embodiment of the present disclosure.

The display panel 200 according to an embodiment of the present disclosure can be applied to various types of display devices. One of the display devices to which the display panel 200 is applied is a wearable display device.

Referring to FIG. 2, a wearable display device 100 according to an embodiment of the present disclosure can include the display panel 200, a frame 20, and a strap 30. In an example, the wearable display device 100 can include a smart watch phone. A display can include the display panel 200 in FIG. 1 including the display area AA and the non-display area NAA1 and NAA2. The frame 20 can be a structure assembled to form an outer appearance of the wearable display device 100. The display panel 200 according to an embodiment of the present disclosure can be placed in a space defined by the frame 20. Accordingly, the screen provided from the display area AA on a front surface of the wearable device 100 can be provided to the user. The strap 30 can be a part for wearing and fixing the wearable display device 100.

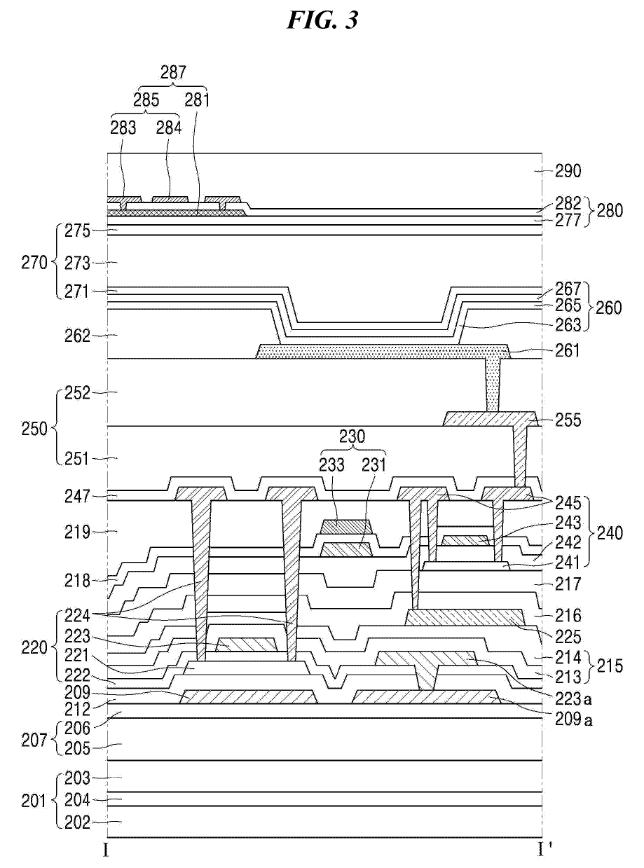

FIG. 3 is a cross-sectional view taken along a line I-I' in FIG. 1. FIG. 3 schematically shows one sub-pixel. In the present disclosure, one sub-pixel is illustrated as an example for convenience of description, but the present disclosure is not limited thereto. The sub-pixel illustrated in FIG. 3 can be disposed on the display area AA.

Referring to FIG. 3, the display panel 200 can include a pixel driving circuit including a plurality of transistors 220 and 240 disposed on a substrate 201, a light-emitting element 260, and a touch sensor 287.

One sub-pixel can include the light-emitting element 260 and the pixel driving circuit that applies a driving current to the light-emitting element 260. The pixel driving circuit can be disposed on the substrate 201, and the light-emitting element 260 can be disposed on the pixel driving circuit. The pixel driving circuit can include the plurality of transistors 220 and 240, and a storage capacitor 230. In one example, the plurality of transistors 220 and 240 can include a first transistor 220 and a second transistor 240.

The substrate 201 can be a flexible plastic substrate. When the substrate 201 is a plastic film, multiple layers of an insulating material can be included. For example, the substrate 201 can include a first base layer 202, a second base layer 203, and a support layer 204. The first base layer 202 and the second base layer 203 can be arranged to be spaced apart from each other in a vertical direction, and the support layer 204 can be disposed therebetween.

A multi-buffer layer 207 can be disposed on the substrate 201. The multi-buffer layer 207 can be a structure in which a first buffer layer 205 and a second buffer layer 206 are arranged in the vertical direction. The first buffer layer 205 and the second buffer layer 206 can cover a surface of the substrate 201. The first buffer layer 205 and the second buffer layer 206 can reduce or prevent penetration of moisture, oxygen, or impurities through the substrate 201. The first buffer layer 205 and the second buffer layer 206 can be composed of a single layer or multiple layers made of an inorganic insulating material such as silicon oxide (SiOx) or silicon nitride (SiNx).

A light-shielding layer 209 can be disposed on the multi-buffer layer 207. The light-shielding layer 209 can prevent external light from being incident on the transistor. To this end, the light-shielding layer 209 can include an opaque metal material. A first metal pattern 209a can be disposed on the multi-buffer layer 207 by being spaced apart from the light-shielding layer 209. The first metal pattern 209a can be made of the same material as the light-shielding layer 209 and formed in the same process as the light-shielding layer 209.

A third buffer layer 212 can be disposed on the light-shielding layer 209. The third buffer layer 212 can protect the transistor from moisture, oxygen, or impurities. The third buffer layer 212 can be composed of a single layer or multiple layers made of an inorganic insulating material such as silicon oxide (SiOx) or silicon nitride (SiNx), but need not be limited thereto. The third buffer layer 212 can cover the light-shielding layer 209 and the first metal pattern 209a.

The first transistor 220 can be disposed on the third buffer layer 212. The first transistor 220 can include a first semiconductor layer 221, a first gate insulating layer 222, a first gate electrode 223, and first source/drain electrodes 224 (or first source and drain electrodes). In an example, the first transistor 220 can be a switching transistor.

The first semiconductor layer 221 can include a channel area and source/drain areas (or source and drain areas). An area of the first semiconductor layer 221 that overlaps the first gate electrode 223 in the vertical direction can be the channel area. The source/drain areas can be arranged on both opposing sides of the channel area, respectively. For example, an area disposed on one side of the channel area among the source/drain areas can be the source area, and an area disposed on the other side of the channel area can be the drain area. The first semiconductor layer 221 can be composed of one or a combination of a polysilicon semiconductor layer and a low-temperature polysilicon semiconductor layer.

The first semiconductor layer 221 can be disposed to overlap the light-shielding layer 209 in the vertical direction. The light-shielding layer 209 can prevent external light from being incident on the first semiconductor layer 221. To this end, the light-shielding layer 209 can have a width at least equal to or greater than that of the first semiconductor layer 221.

The first gate insulating layer 222 can be disposed between the first semiconductor layer 221 and the first gate electrode 223. The first gate insulating layer 222 can extend outward while covering the first semiconductor layer 221. The first gate insulating layer 222 can be composed of a single layer or multiple layers made of an inorganic insulating material such as silicon oxide (SiOx) or silicon nitride (SiNx).

The first gate electrode 223 can be disposed on the first gate insulating layer 222. The first source/drain electrodes 224 can be electrically connected to the first semiconductor layer 221 of the first transistor 220. In one example, the first source/drain electrodes 224 can be referred to as first input/output electrodes. The first source/drain electrodes 224 can be arranged on both opposing sides with the first gate electrode 223 interposed therebetween and can be in contact with the source area and the drain area of the first semiconductor layer 221, respectively. For example, one of the first source/drain electrodes 224 can be a source electrode in contact with the source area of the first semiconductor layer 221. For example, the other of the first source/drain electrodes 224 can be a drain electrode in contact with the drain area of the first semiconductor layer 221. When the first transistor 220 is the switching transistor, the source electrode can be an input electrode to which the data signals provided from the data lines DL (see FIG. 1) are input. The drain electrode can transmit the data signals to the second transistor 240. The drain electrode can be an output electrode that transmits the data signals. A second metal pattern 223a can be disposed on the first gate insulating layer 222 by being spaced apart from the first gate electrode 223. The second metal pattern 223a can be made of the same material and formed in the same process as the first gate electrode 223. The second metal pattern 223a can be disposed to overlap the first metal pattern 209a in the vertical direction. A portion of the second metal pattern 223a can extend through the first gate insulating layer 222 and the third buffer layer 212 and be in direct contact with the first metal pattern 209a.

A lower interlayer insulating structure 215 can be disposed on the first gate electrode 223. The lower interlayer insulating structure 215 can include a first interlayer insulating layer 213 and a second interlayer insulating layer 214 disposed on the first interlayer insulating layer 213. The first interlayer insulating layer 213 can cover the first gate electrode 223. The first interlayer insulating layer 213 and the second interlayer insulating layer 214 can be composed of a single layer or multiple layers made of an inorganic insulating material such as silicon oxide (SiOx) or silicon nitride (SiNx).

A third interlayer insulating layer 216 can be disposed on the second interlayer insulating layer 214. A third metal pattern 225 can be disposed at a different position spaced apart from the first transistor 220. The third metal pattern 225 can be disposed between the second interlayer insulating layer 214 and the third interlayer insulating layer 216.

The third metal pattern 225 can include a transition metal material having hydrogen-friendly properties with a hydrogen capture effect. For example, the third metal pattern 225 can include titanium (Ti). This will be described later.

A fourth buffer layer 217 can be disposed on the third interlayer insulating layer 216. The fourth buffer layer 217 can protect the transistor from moisture, oxygen, or impurities. The fourth buffer layer 217 can be composed of a single layer or multiple layers made of an inorganic insulating material such as silicon oxide (SiOx) or silicon nitride (SiNx).

The second transistor 240 can be disposed on the fourth buffer layer 217 at a different position spaced apart from the first transistor 220. The second transistor 240 can be electrically connected to the first transistor 220. For example, the second transistor 240 can include a second semiconductor layer 241, a second gate insulating layer 242, a second gate electrode 243, and second source/drain electrodes 245 (or second source and drain electrodes). In one example, the second transistor 240 can be a driving transistor electrically connected to the light-emitting element 260. However, FIG. 3 illustrates the connection relationships or the like to describe an example of a method for supplying the driving current to the light-emitting element 260, and the present disclosure is not limited thereto. For example, another switching transistor or another light emissive transistor can be further disposed between the light-emitting element 260 and the second transistor 240.

The second semiconductor layer 241 can include a channel area and source/drain areas. An area of the second semiconductor layer 241 that overlaps the second gate electrode 243 in the vertical direction can be the channel area. The source/drain areas can be arranged on both opposing sides of the channel area, respectively. The second semiconductor layer 241 can be constructed as an oxide semiconductor layer. For example, at least one of oxide semiconductor materials such as indium gallium zinc oxide (IGZO) or indium zinc oxide (IZO) can be included. In one example, the second semiconductor layer 241 can be disposed to at least partially overlap the first metal pattern 209a and the second metal pattern 223a in the vertical direction. Accordingly, external light can be prevented from being incident from the outside of the substrate 201 onto the second semiconductor layer 241 by the metal patterns 209a and 223a. Accordingly, characteristics of the second transistor 240 can be prevented from being changed by external light.

In addition, the second semiconductor layer 241 can be disposed to overlap the third metal pattern 225 in the vertical direction. Because the third metal pattern 225 includes a transition metal material capable of capturing hydrogen, hydrogen can be prevented from being introduced into the second semiconductor layer 241 including the oxide semiconductor material. To this end, it is preferable that the third metal pattern 225 is formed to have a size greater than a width of the second semiconductor layer 241.

The second gate insulating layer 242 can be disposed between the second semiconductor layer 241 and the second gate electrode 243. The second gate insulating layer 242 can be composed of a single layer or multiple layers made of an inorganic insulating material such as silicon oxide (SiOx) or silicon nitride (SiNx).

The first gate electrode 223 or the second gate electrode 243 can be composed of a single layer or multiple layers made of one of molybdenum (Mo), aluminum (Al), chromium (Cr), gold (Au), titanium (Ti), nickel (Ni), neodymium (Nd), and copper (Cu), or an alloy thereof. However, it is not limited to such materials.

An upper interlayer structure 218 and 219 can be disposed on the second gate electrode 243. The upper interlayer structure 218 and 219 can include a fourth interlayer insulating layer 218 and a fifth interlayer insulating layer 219. The fourth interlayer insulating layer 218 and the fifth interlayer insulating layer 219 can be composed of a single layer or multiple layers made of an inorganic insulating material such as silicon oxide (SiOx) and silicon nitride (SiNx).

The fourth interlayer insulating layer 218 can cover the second gate electrode 243. The storage capacitor 230 can include a first storage electrode 231 and a second storage electrode 233. For example, the first storage electrode 231 can be located at the same layer as the second gate electrode 243. For example, the first storage electrode 231 can be made of the same material as the second gate electrode 243. The first storage electrode 231 can be located on the second gate insulating layer 242 at a different position spaced apart from the second gate electrode 243. The second storage electrode 233 can be disposed on the fourth interlayer insulating layer 218 so as to overlap the first storage electrode 231 in the vertical direction.

The first storage electrode 231 and the second storage electrode 233 can be composed of a single layer or multiple layers made of one of molybdenum (Mo), aluminum (Al), chromium (Cr), gold (Au), titanium (Ti), nickel (Ni), neodymium (Nd), and copper (Cu), or an alloy thereof. However, the present disclosure is not limited to such materials. The second storage electrode 233 can be covered with the fifth interlayer insulating layer 219.

The first source/drain electrodes 224 and the second source/drain electrodes 245 can be disposed on the fifth interlayer insulating layer 219. The first source/drain electrodes 224 can be in direct contact with and be connected to the source/drain areas of the first semiconductor layer 221, respectively, by extending through the upper interlayer structure 218 and 219, the fourth buffer layer 217, the third interlayer insulating layer 216, a lower interlayer structure 215, and the first gate insulating layer 222. The first source/drain electrodes 224 can be arranged on both opposing sides with the first gate electrode 223 interposed therebetween.

The second source/drain electrodes 245 can be in direct contact with and be connected to the source/drain areas of the second semiconductor layer 241, respectively, by extending through the upper interlayer structure 218 and 219. A portion of the second source/drain electrodes 245 of the second transistor 240 can be electrically connected to the third metal pattern 225. For example, the portion of the second source/drain electrodes 245 can be in direct contact with and be connected to the third metal pattern 225 by extending through the upper interlayer structure 218 and 219, the second gate insulating layer 242, the fourth buffer layer 217, and the third interlayer insulating layer 216. In one example, the second source/drain electrodes 245 can be referred to as second input/output electrodes. The second source/drain electrodes 245 can be arranged on both opposing sides with the second gate electrode 243 interposed therebetween and be in contact with the source area and the drain area of the second semiconductor layer 241, respectively. For example, one of the second source/drain electrodes 245 can be a source electrode in contact with the source area of the second semiconductor layer 241. For example, the other of the second source/drain electrodes 245 can be a drain electrode in contact with the drain area of the second semiconductor layer 241. When the second transistor 240 is the driving transistor, the source electrode can be an input electrode to which the data signals provided from the data lines DL (see FIG. 1) are input. The drain electrode can transmit the driving current to the light-emitting element 260. The drain electrode can be an output electrode from which the driving current is emitted.

The first source/drain electrodes 224 or the second source/drain electrodes 245 can be composed of a single layer or multiple layers made of one of molybdenum (Mo), aluminum (Al), chromium (Cr), gold (Au), titanium (Ti), nickel (Ni), neodymium (Nd), and copper (Cu), or an alloy thereof, but need not be limited thereto.

A passivation layer 247 can be disposed on the first source/drain electrodes 224 or the second source/drain electrodes 245. The passivation layer 247 can be composed of a single layer or multiple layers including an inorganic insulating material such as silicon oxide, silicon nitride, and silicon oxynitride. The passivation layer 247 can protect the pixel driving circuit disposed underneath.

A planarization layer 250 can be disposed on the passivation layer 247. The planarization layer 250 can planarize a step caused by the pixel driving circuit underneath. The planarization layer 250 can be disposed in a structure in which a plurality of planarization layers are stacked from bottom to top. For example, in the drawing, the planarization layer 250 is illustrated in a structure in which a first planarization layer 251 and a second planarization layer 252 are stacked in the vertical direction, but is not limited thereto. For example, a multi-layered structure in which a third planarization layer is further deposited on the second planarization layer 252 can be included. For example, the planarization layer 250 can include an organic insulating material such as polyimide or acrylic resin.

A pixel contact electrode 255 can be disposed on the first planarization layer 250. The pixel contact electrode 255 can extend through the first planarization layer 250 and the passivation layer 247 and be in direct contact with the second source/drain electrodes 245 of the second transistor 240.

The light-emitting element 260 can be formed on the planarization layer 250. For example, the light-emitting element 260 can be disposed on the second planarization layer 252. The light-emitting element 260 can include a first electrode 261, a light emissive layer 263, a second electrode 265, and a capping layer 267.

The light-emitting element 260 can be electrically connected to the pixel driving circuit via the first electrode 261. For example, the first electrode 261 can extend through the second planarization layer 252 and be in direct contact with the pixel contact electrode 255. Accordingly, the first electrode 261 can be electrically connected to the second transistor 240 via the pixel contact electrode 255. However, FIG. 2 is for describing an example of a method for supplying current to the first electrode, and the present disclosure is not limited to a physical contact between the second transistor 240, which is the driving transistor, and the first electrode 261. In one example, the switching transistor electrically connected to the first electrode 261 can be the light emissive transistor. For example, the light emissive transistor can control turned on and turned off states of the light-emitting element 260. The pixel contact electrode 255 can include a conductive material. For example, the pixel contact electrode 255 can include a metal material such as aluminum (Al), chromium (Cr), copper (Cu), titanium (Ti), molybdenum (Mo), and tungsten (W). In one example, the pixel contact electrode 255 can have a multi-layered structure of titanium/aluminum/titanium (Ti/Al/Ti). In one example, the pixel contact electrode 255 can be electrically connected to a high-potential power supply (VDD) line.

The first electrode 261 can include a transparent conductive film. For example, the first electrode 261 can include indium tin oxide (ITO) or indium zinc oxide (IZO). Alternatively, the first electrode 261 can include a single-layered or multi-layered structure including a reflective metal film made of one of silver (Ag), aluminum (Al), gold (Au), nickel (Ni), and chromium (Cr), or an alloy thereof. The first electrode 261 can also be referred to as an anode electrode or a pixel electrode.

A bank 262 can be disposed on the first electrode 261. The bank 262 can be disposed to cover an edge of the first electrode 261. A portion of the bank 262 can extend onto and along the second planarization layer 252. A top surface of the first electrode 261 that is not covered by the bank 262 and is exposed can become a light emissive area. The bank 262 can include a black material, a light-shielding material, or a light-absorbing material. The bank 262 can include a material that absorbs light in a specific wavelength range. The bank 262 can be in a structure in which at least two color filters of different colors among a red color filter, a green color filter, and a blue color filter are stacked. The bank 262 can be made of an organic insulating material. The bank 262 can include, for example, photosensitive polyimide, photoacrylic, or benzocyclobutene (BCB).

The light emissive layer 263 can be disposed on the first electrode 261. The light emissive layer 263 can include a hole transport layer (HTL), an organic light emissive layer (EML), an electron transport layer (ETL), a hole blocking layer (HBL), a hole injection layer (HIL), an electron blocking layer (EBL), and an electron injection layer (EIL) as components. The light emissive layer 263 can have a multi-stack structure in which two or more organic light emissive layers (EMLs) are stacked. Among the components of the light emissive layer 263, the electron injection layer (EIL), the electron blocking layer (EBL), the hole transport layer (HTL), and the hole blocking layer (HBL) can be disposed as common layers on an entire area of the display area AA and a portion of the non-display area AA. In addition, the organic light emissive layer (EML) can be disposed only on the pixels on the display area AA. Alternatively, the organic light emissive layer (EML) can be disposed as a common layer on the display area AA and the non-display area AA.

The second electrode 265 can be disposed on the light emissive layer 263. The second electrode 265 can be commonly connected to the light emissive layer 263 formed on all the pixels P, for example. Therefore, the second electrode 265 can also be referred to as a cathode electrode or a common electrode. The second electrode 265 can include a semi-transparent conductive material. For example, the second electrode 265 can be made of a metal material such as magnesium (Mg), silver (Ag), or an alloy (Ag-Mg) of silver (Ag) and magnesium (Mg). In one example, the second electrode 265 can include a transparent conductive film made of indium-tin-oxide (ITO) or indium-zinc-oxide (IZO). In one example, the display area AA can include a plurality of transmission areas. When the transmission areas are present in the display area AA, the second electrode 265 can be disposed on the display area AA so as not to overlap with the transmission areas. For example, the transmission areas can be areas where no opaque material or reflective material is disposed.

A capping layer 267 can be disposed on the second electrode 265. The capping layer 267 can prevent light generated from the light emissive layer 263 from being lost, thereby improving light extraction efficiency.

An encapsulation stack 270 can be disposed on the light-emitting element 260. The encapsulation stack 270 can protect the light-emitting element 260 from external oxygen or moisture. The encapsulation stack 270 can cover the display area AA and extend onto the non-display area NAA located outward of the display area AA.

The encapsulation stack 270 can include a multi-layered structure in which a first encapsulation layer 271, a second encapsulation layer 273, and a third encapsulation layer 275 are disposed. The second encapsulation layer 273 can be a component that is disposed between the first encapsulation layer 271 and the third encapsulation layer 275.

The first encapsulation layer 271 can be disposed on a capping layer 267. The second encapsulation layer 273 can be disposed on the first encapsulation layer 271. The second encapsulation layer 273 can cover the first encapsulation layer 271 and can have a sufficient thickness to have a flat surface. The second encapsulation layer 273 can prevent foreign substances from penetrating into the light-emitting element 260. The third encapsulation layer 275 can be disposed on the second encapsulation layer 273.

Each of the first encapsulation layer 271 and the third encapsulation layer 275 can include an inorganic insulating material, and the second encapsulation layer 273 can include an organic insulating material. For example, each of the first encapsulation layer 271 and the third encapsulation layer 275 can include at least one material among silicon nitride (SiNx), silicon oxide (SiOx), and silicon oxynitride (SiON). The second encapsulation layer 273 can include at least one material among epoxy, polyimide, polyethylene, and acrylate.

A touch unit can be disposed on the encapsulation stack 270. The touch unit can include a touch buffer layer 277, the touch sensor 287, a touch interlayer insulating layer 282, and a touch protective layer 290.

The touch buffer layer 277 can be disposed on the third encapsulation layer 275. The touch buffer layer 277 can relieve stress between the encapsulation stack 270 and the touch sensor 287, thereby preventing the encapsulation stack 270 and the light-emitting element 260 from being damaged. The touch buffer layer 277 can include an inorganic insulating material. For example, the touch buffer layer 277 can include silicon nitride (SiNx).

The touch sensor 287 can include a plurality of touch electrodes 285 and a bridge electrode 281. The plurality of touch electrodes 285 and the bridge electrode 281 can be disposed at different layers. For example, the bridge electrode 281 can be disposed on the touch buffer layer 277. The plurality of touch electrodes 285 can be disposed on the touch interlayer insulating layer 282. The plurality of touch electrodes 285 can include a first touch electrode 283 and a second touch electrode 284. The bridge electrode 281 can electrically connect adjacent first touch electrodes 283 to each other. To this end, the first touch electrode 283 can extend through the touch interlayer insulating layer 282 and be in contact with the bridge electrode 281. The touch interlayer insulating layer 282 can include an inorganic insulating material. For example, the touch interlayer insulating layer 282 can include silicon nitride (SiNx).

The first touch electrode 283, the second touch electrode 284, or the bridge electrode 281 can include a conductive material. The first touch electrode 283, the second touch electrode 284, or the bridge electrode 281 can include a single layer or multiple layers made of one of molybdenum (Mo), aluminum (Al), chromium (Cr), gold (Au), titanium (Ti), nickel (Ni), neodymium (Nd), and copper (Cu) or an alloy thereof.

The touch buffer layer 277 and the touch interlayer insulating layer 282 can be in contact with each other in the vertical direction to constitute a touch insulating structure 280. The touch protective layer 290 can be disposed on the touch sensor 287. The touch protective layer 290 can prevent damage to the touch sensor 287 resulted from external impact and moisture. The touch protective layer 290 can include an organic insulating material. For example, the touch protective layer 290 can include a photosensitive acrylic or polyimide organic material.

In one example, to improve product characteristics of the display panel 200 applied to the wearable display device 100 such as the smart watch phone, the second semiconductor layer 241 of the second transistor 240 in FIG. 3, which is the driving transistor, can include an oxide semiconductor layer. Because the second semiconductor layer 241 is the oxide semiconductor layer, the second transistor 240 can be an oxide thin-film transistor.

When the second transistor 240 is the oxide thin-film transistor, hysteresis characteristics of the element can be ameliorated. For example, the oxide thin-film transistor can have a smaller hysteresis than a thin-film transistor to which a polysilicon semiconductor layer is applied. When the hysteresis is large, a threshold voltage can shift significantly, which can degrade an operational stability of the light-emitting element. On the other hand, when the hysteresis is small, there is almost no change in the threshold voltage shift, so that the light-emitting element can operate stably, which can increase operational reliability.

However, the oxide semiconductor layer that constitutes the oxide thin-film transistor is sensitive to hydrogen. Accordingly, when the oxide thin-film transistor is exposed to hydrogen, the threshold voltage shifts in a negative direction, causing a phenomenon in which current flows even at a low gate voltage, which can cause a problem such as a bright dot defect.

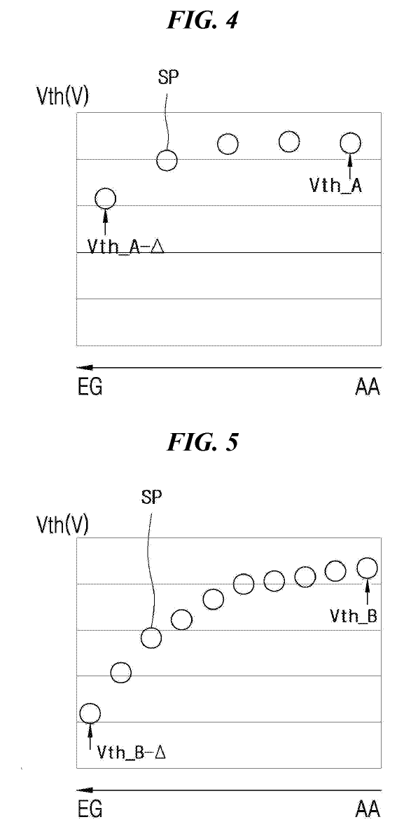

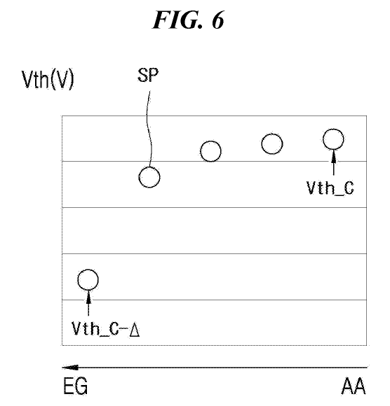

FIGS. 4 to 6 are diagrams showing threshold voltage values measured based on locations on a display panel. In FIGS. 4 to 6, an X-axis can represent a position of a sub-pixel measured while moving from the display area AA of the display panel to an edge area EG. A Y-axis can represent a threshold voltage value V. For example, FIG. 4 shows measurement at a lower portion of the display panel 200, FIG. 5 shows measurement at a left or right portion of the display panel 200, and FIG. 6 shows measurement at an upper portion of the display panel 200.

Referring to FIGS. 4 to 6, it can be seen that at all of the measurement locations such as the upper, lower, left, or right portion of the display panel 200, the threshold voltage value V shifts in the negative (-) direction from reference threshold voltage values Vth_A, Vth_B, and Vth_C to displaced threshold voltage values Vth_A-△, Vth_B-△, and Vth_C-△ as the position moves from the display area AA toward the edge area EG. The displaced threshold voltage values Vth_A-△, Vth_B-△, and Vth_C-△ can be smaller values than the reference threshold voltage values Vth_A, Vth_B, and Vth_C. Accordingly, the bright dot defect in which the sub-pixel SP disposed on the edge area EG of the display panel 200 emits light regardless of an operation signal can occur.

Therefore, to prevent the occurrence of the bright dot defect or the like and apply the oxide thin-film transistor as the driving transistor, it is important to block hydrogen from being introduced from the outside of the display panel 200.

The display device according to an embodiment of the present disclosure can include a plurality of barrier structures that can prevent characteristics of an oxide semiconductor from being changed by hydrogen penetration into the driving transistor. The plurality of barrier structures can block hydrogen from being introduced from the edge area of the display panel 200 to the display area AA. Accordingly, the plurality of barrier structures can prevent the bright dot defect from occurring by the threshold voltage value shift in the negative direction resulted from hydrogen penetration into the driving transistor.

The plurality of barrier structures can be disposed on the bezel area surrounding the outer side of the display area AA. For example, the plurality of barrier structures can be disposed on an entire area of the bezel area. For example, the plurality of barrier structures can be arranged at locations such as the upper, lower, left, or right portions of the display panel 200. In addition, the plurality of barrier structures can be arranged to surround sub-pixels SP arranged at an outermost area adjacent to the bezel area among the sub-pixels SP on the display area AA. The plurality of barrier structures can be formed in the same process as the components constituting the sub-pixels SP on the display area AA. For example, the barrier structures can be referred to as dummy sub-pixels.

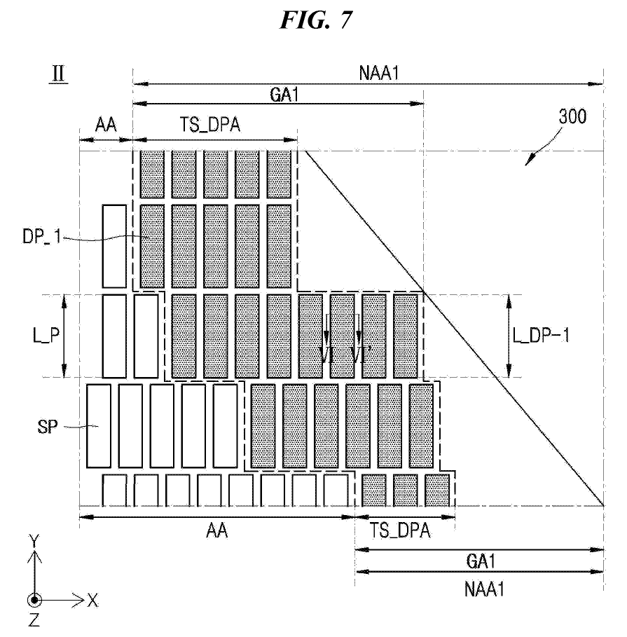

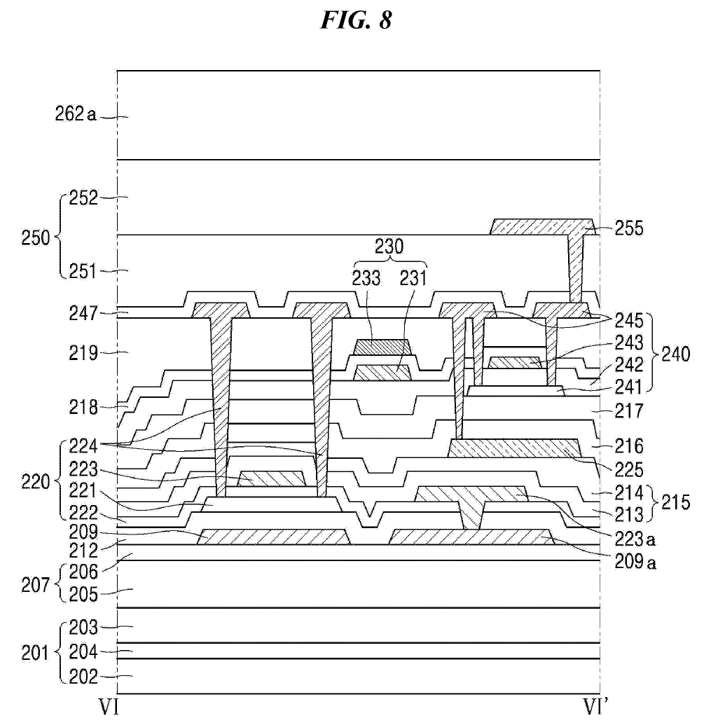

FIG. 7 is an enlarged view of an area 'II' in FIG. 1. FIG. 8 is a cross-sectional view taken along a line VI-VI' in FIG. 7. For example, FIG. 7 can represent a corner of the bezel area, such as an upper corner (the first corner) of the bezel area of the first non-display area NAA1 of the display panel 200. FIG. 8 can represent a barrier structure of a first size among the barrier structures. For example, one of the barrier structures of the first size can be referred to as a first dummy sub-pixel DP_1. In FIG. 8, components the same as those in FIG. 5 can be denoted by the same reference numerals. Accordingly, redundant descriptions will be omitted or only briefly made, and differences will be described.

Referring to FIG. 7, the plurality of sub-pixels SP can be arranged on the display area AA. The plurality of sub-pixels SP can be the sub-pixels SP arranged at the outermost area of the display area AA. Each sub-pixel SP can have a first length L_P. One sub-pixel SP disposed on the display area AA can include the same components as those of the sub-pixel in FIG. 3. For example, the second transistor 240, which is the driving transistor, can include the second semiconductor layer 241, which is the oxide semiconductor.

The first non-display area NAA1 can be defined outward of the display area AA. The first non-display area NAA1 can include a first dummy pixel area TS_DPA and a link line area 300. A power line or a signal line including the high-potential power supply (VDD) line can be disposed on the link line area 300. The link line area 300 can be referred to as a gate in panel (GIP) line area. The link line area 300 can be an edge area surrounding the upper, lower, left, or right portions of the display panel 200. The first dummy pixel area TS_DPA can be defined at the upper corner of the bezel area of the first non-display area NAA1. The plurality of first dummy sub-pixels DP_1 can be arranged at the first dummy pixel area TS_DPA. Each of the first dummy sub-pixels DP_1 can have a second length L_DP-1. The second length L_DP-1 of the first dummy sub-pixel DP_1 can be equal to the first length L_P of the sub-pixel SP disposed at the outermost area of the display area AA.

The first non-display area NAA1 can include a first gap area GA1 defined between the display area AA and the link line area 300. A portion of the first gap area GA1 adjacent to the display area AA in the first non-display area NAA1 can be filled by the plurality of first dummy sub-pixels DP_1 arranged on the first dummy pixel area TS_DPA. For example, at least two rows of the plurality of first dummy sub-pixels DP_1 can be arranged outward of the sub-pixels SP arranged at the outermost area of the display area AA.

The first dummy sub-pixel DP_1 can include a configuration in which the third metal pattern that captures hydrogen is disposed to overlap the second semiconductor layer 241. This will be described below with reference to FIG. 8.

Referring to FIGS. 7 and 8, the first dummy sub-pixel DP_1 can have the lower interlayer insulating structure 207, the light-shielding layer 209, and the third buffer layer 212 disposed between the first transistor 220 and the substrate 201. The first transistor 220 can include the first semiconductor layer 221, the first gate insulating layer 222, the first gate electrode 223, and the first source/drain electrodes 224.

The second transistor 240 and the storage capacitor 230 can be disposed at different locations spaced apart from the first transistor 220. The second transistor 240 can include the second semiconductor layer 241, the second gate insulating layer 242, the second gate electrode 243, and the second source/drain electrodes 245. The second semiconductor layer 241 of the second transistor 240 can be formed as the oxide semiconductor layer. For example, the second semiconductor layer 241 can include at least one of oxide semiconductor materials such as indium gallium zinc oxide (IGZO) or indium zinc oxide (IZO).

The upper interlayer structure 218 and 219 including the fourth interlayer insulating layer 218 and the fifth interlayer insulating layer 219 can be disposed on the second gate electrode 243 of the second transistor 240.

The first source/drain electrodes 224 and the second source/drain electrodes 245 can be disposed on the fifth interlayer insulating layer 219. The first source/drain electrodes 224 can be connected to the source/drain areas of the first semiconductor layer 221 by extending through the insulating layers disposed thereunder, respectively. The second source/drain electrodes 245 can be in direct contact with and connected to the source/drain areas of the second semiconductor layer 241 by extending through the upper interlayer structure 218 and 219, respectively. Portions of the second source/drain electrodes 245 of the second transistor 240 can be in direct contact with the third metal pattern 225 by extending through the insulating layers disposed thereunder.

The storage capacitor 230 can include the first storage electrode 231 and the second storage electrode 233 that overlap each other in the vertical direction with the fourth interlayer insulating layer 218 of the upper interlayer structure 218 and 219 interposed therebetween.

The passivation layer 247 including the inorganic insulating material can cover the first source/drain electrodes 224 and the second source/drain electrodes 245.

The first planarization layer 250 can be disposed on the passivation layer 247. The pixel contact electrode 255 can be disposed on the first planarization layer 251. The pixel contact electrode 255 can be disposed on the second transistor 240. A portion of the pixel contact electrode 255 can be in direct contact with one of the second source/drain electrodes 245 by extending through the first planarization layer 251 and the passivation layer 247.

In the first dummy sub-pixel DP_1, the pixel contact electrode 255 is electrically connected to the pixel contact electrode 255 of the display area AA, and thus is able to be electrically connected to the high-potential power supply (VDD) line. For example, the high-potential power supply (VDD) line can be disposed on the link line area 300 of the first non-display area NAA1.

The second planarization layer 252 can be disposed on the first planarization layer 251 and the pixel contact electrode 255. The pixel contact electrode 255 of the first dummy sub-pixel DP_1 is covered by the second planarization layer 252. Accordingly, the second transistor 240 of the first dummy sub-pixel DP_1 can be a dummy transistor that does not function as the driving transistor.

The planarization layer 250 can be composed of the first planarization layer 251 and the second planarization layer 252. The planarization layer 250 can flatten the step caused by the lower circuit structure.

An organic insulating structure 262a can be disposed on the planarization layer 250. The organic insulating structure 262a can be made of the same material as the bank 262 and be formed in the same process as the bank 262 on the display area AA. The organic insulating structure 262a can cover an entire surface of the second planarization layer 252 in the first dummy sub-pixel DP_1.

In the first dummy sub-pixel DP_1, the second semiconductor layer 241 of the second transistor 240 can be disposed to overlap the third metal pattern 225 in the vertical direction. The third metal pattern 225 can include the transition metal material capable of capturing hydrogen. Accordingly, hydrogen can be prevented from being introduced into the second semiconductor layer 241 including the oxide semiconductor material. For example, the third metal pattern 225 can include titanium (Ti). The third metal pattern 225 can be formed to have a size greater than a width of the second semiconductor layer 241 to prevent the second semiconductor layer 241 from being exposed to hydrogen.

The plurality of first dummy sub-pixels DP_1 can be arranged along the first direction (X) or the second direction (Y) outward of the sub-pixels SP arranged at the outermost area of the display area AA. Each of the first dummy sub-pixels DP_1 can be a barrier structure that blocks the hydrogen inflow. In addition, the plurality of first dummy sub-pixels DP_1 can be arranged outward of the sub-pixels SP arranged at the outermost area. Accordingly, the first dummy sub-pixels DP_1 can be arranged in a multi-stage structure to block the hydrogen inflow. Therefore, the plurality of first dummy sub-pixels DP_1 can prevent hydrogen from being introduced from outside of an upper corner distal end of the display panel 200 to the sub-pixels SP on the display area AA. In addition, the plurality of first dummy sub-pixels DP_1 can be arranged at the first gap area GA1 of the first non-display area NAA1 at the upper corner of the bezel area. Accordingly, the upper corner of the bezel area of the first non-display area NAA1 does not require additional space even when the barrier structures are arranged in the multi-stage structure, so that the bezel area can be minimized.

According to an embodiment of the present disclosure, a structure in the area 'II', which is at the first corner of the display panel 200, can also be present in the fourth corner of the display panel. In this light, the first dummy sub-pixels DP_1 can be arranged in the X-axis direction from the display area AA to the link line area 300 or arranged in the Y-Axis direction from the display area AA to the link line area 300 in columns, so one or more first dummy sub-pixel DP_1 can separate the sub-pixel SP disposed at the outermost area of the display area AA and the link line area 300, for each row or column of the first dummy sub-pixels DP_1. In embodiments of the present disclosure, the number of first dummy sub-pixels DP_1 in the first dummy pixel area TS_DPA can be the same or different from row to row or column to column. In the first dummy pixel area TS_DPA, a step structure can be formed between adjacent rows or columns of the first dummy sub-pixels DP_1.

According to an embodiment of the present disclosure, the organic insulating structure 262a can be disposed on the planarization layer 250 as a sheet without any recess thereon in the first dummy pixel area TS_DPA. For example, the organic insulating structure 262a does not cover the first electrode 261 in the first dummy pixel area TS_DPA, and the first dummy pixel area TS_DPA can be without the light emitting element 260.

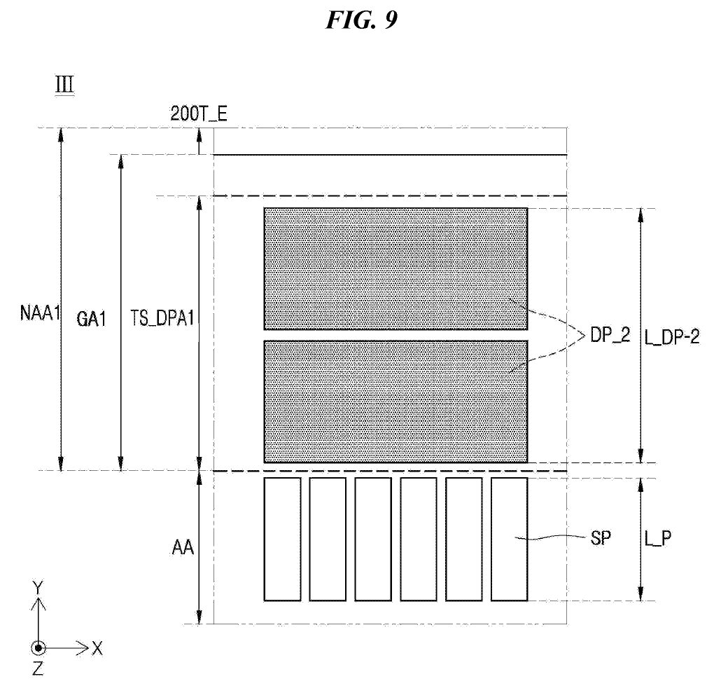

FIG. 9 is an enlarged view of an area 'III' in FIG. 1. For example, it can show an upper portion of the bezel area of the first non-display area NAA1 of the display panel 200. Referring to FIG. 9, the plurality of sub-pixels SP can be arranged on the display area AA. The plurality of sub-pixels SP can be the sub-pixels SP arranged at the outermost area of the display area AA. Each sub-pixel SP can have the first length L_P. One sub-pixel SP disposed on the display area AA can include the same components as those of the sub-pixel in FIG. 3. For example, the second transistor 240, which is the driving transistor, can include the second semiconductor layer 241, which is the oxide semiconductor.

The first non-display area NAA1 can be defined outward of the display area AA. The first non-display area NAA1 can include the first gap area GA1. The first gap area GA can include a second dummy pixel area TS_DPA1. A plurality of second dummy sub-pixels DP_2 can be arranged at the second dummy pixel area TS_DPA1.

The second dummy sub-pixel DP_2 can include the configuration of the first dummy sub-pixel DP_1 in FIG. 8. For example, the second dummy sub-pixel DP_2 can include the same component as the second semiconductor layer 241 (see FIG. 8), which is the oxide semiconductor. In addition, the second dummy sub-pixel DP_2 can be disposed such that the third metal pattern 225 (see FIG. 8) for capturing hydrogen overlaps the second semiconductor layer 241.

The second dummy sub-pixels DP_2 can be arranged in at least two columns of a first column adjacent to the sub-pixels SP arranged at the outermost area of the display area AA and a second column outward of the first column. For example, a length of one second dummy sub-pixel DP_2 can be equal to the first length L_P of the sub-pixel SP of the display area AA. In addition, a total length of the second dummy sub-pixels DP_2 arranged in the two columns on the second dummy pixel area TS_DPA1 can be a second length L_DP-2. The second length L_DP-2 can be greater than the first length L_P.

A portion of the first gap area GA1 adjacent to the display area AA in the first non-display area NAA1 can be filled with the plurality of second dummy sub-pixels DP_2. For example, the plurality of second dummy sub-pixels DP_2 can be arranged in at least two columns in the second direction (Y) of the display area AA. Accordingly, the second dummy sub-pixels DP_2 capable of blocking the hydrogen inflow can be arranged in a multi-stage structure. The second dummy sub-pixel DP_2 can be one of the barrier structures having the first size. In addition, the second dummy sub-pixel DP_2 can be referred to as a second barrier structure. Therefore, hydrogen can be prevented from being introduced into the sub-pixel SP on the display area AA in a direction of an upper distal end 200T_E of the display panel 200. In addition, the plurality of second dummy sub-pixels DP_2 can be arranged at the first gap area GA1 of the first non-display area NAA1 at the upper portion of the bezel area. Accordingly, even when the second barrier structures arranged in the multi-stage structure are arranged on the upper portion of the bezel area, no additional space is required, so that the bezel area can be minimized.

According to an embodiment of the present disclosure, a structure in the area 'III', which is at the upper portion of the display panel 200, can also be present in the right side portion and the left side portion of the display panel 200. In this light, the second dummy sub-pixels DP_2 can be arranged in the Y-axis direction from the display area AA to the upper distal end 200T_E of the display panel 200 at the upper portion of the display panel 200, and the second dummy sub-pixels DP_2 can be arranged in the X-axis direction from the display area AA to the link line area 300 when at the right side portion and the left side portion of the display panel 200. Accordingly, one or more second dummy sub-pixel DP_2 can separate the sub-pixel SP disposed at the outermost area of the display area AA and the upper distal end 200TE_E and the link line area 300.

According to an embodiment of the present disclosure, the organic insulating structure 262a can be disposed on the planarization layer 250 as a sheet without any recess thereon in the second dummy pixel area TS_DPA1. For example, the organic insulating structure 262a does not cover the first electrode 261 in the second dummy pixel area TS_DPA1 since the second dummy pixel area TS_DPA1 can be without the light emitting element 260.

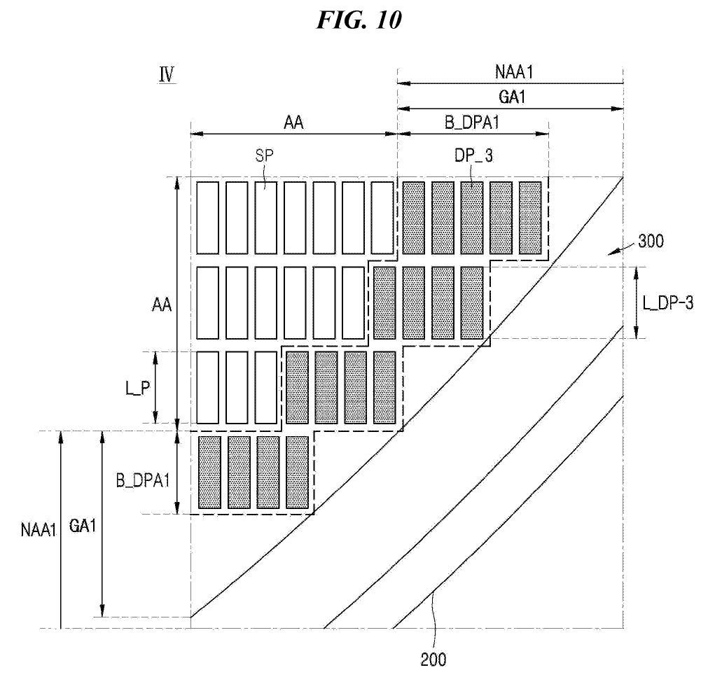

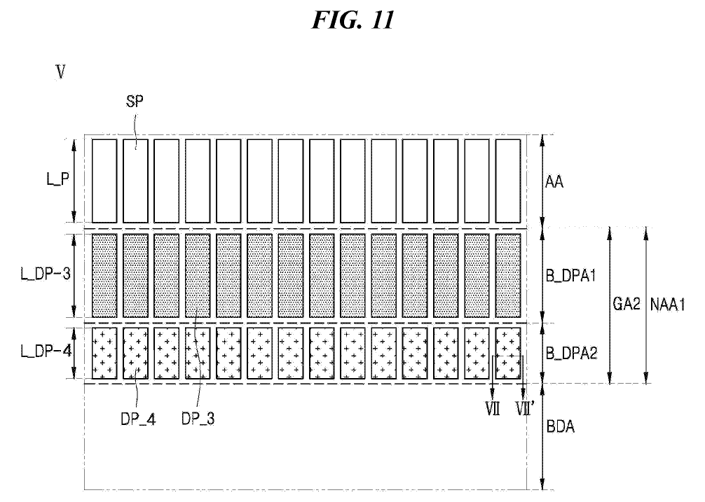

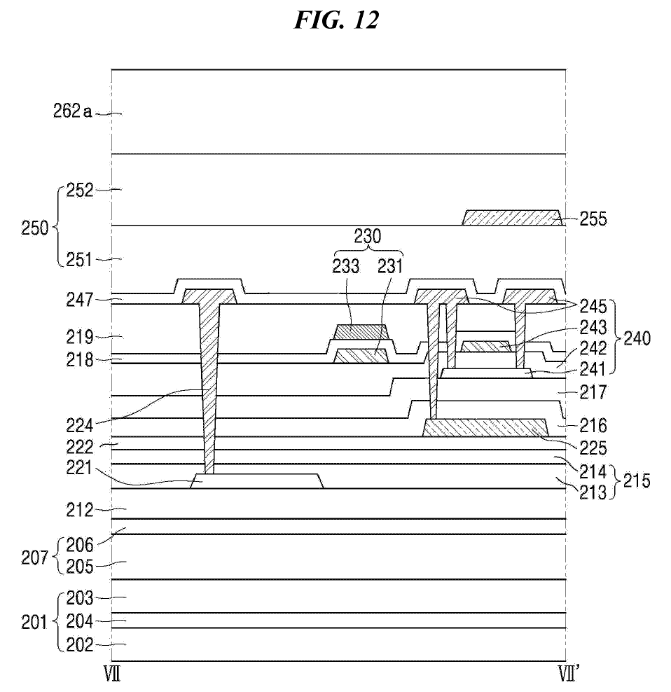

FIG. 10 is an enlarged view of an area 'IV' in FIG. 1. FIG. 11 is an enlarged view of an area 'V' in FIG. 1. FIG. 12 is a cross-sectional view taken along a line VII-VII' in FIG. 11. In FIGS. 10 to 12, the same components as those in FIGS. 7 and 8 can be denoted by the same reference numerals. Accordingly, redundant descriptions will be omitted or only briefly made, and differences will be described. For example, FIG. 10 can represent a lower corner facing the lower portion of the display panel 200. FIG. 11 can represent a lower portion of the bezel area of the first non-display area NAA1 of the display panel 200.

Referring to FIG. 10, the plurality of sub-pixels SP can be arranged at the outermost area of the display area AA. In FIG. 10, the outermost area of the display area AA can be an area closest to the bezel area. Each sub-pixel SP can have the first length L_P. One sub-pixel SP disposed on the display area AA can include the same components as those of the sub-pixel in FIG. 3. For example, the second semiconductor layer 241, which is the oxide semiconductor, can be included in the second transistor 240, which is the driving transistor.

The first non-display area NAA1 can be disposed outward of the display area AA. The first non-display area NAA1 can include a third dummy pixel area B_DPA1 and the link line area 300 defined outward of the display area AA. The power line or the signal line including the high-potential power supply (VDD) line can be disposed on the link line area 300. The link line area 300 can be referred to as the GIP line area. The link line area 300 can be the edge area surrounding the upper, lower, left, or right portions of the display panel 200. The third dummy pixel area B_DPA1 can be defined at a lower corner of the bezel area of the first non-display area NAA1. In one example, the third dummy pixel area B_DPA1 and the link line area 300 can extend to the bezel area downward of the display panel 200.

A plurality of third dummy sub-pixels DP_3 can be arranged at a third dummy pixel area B_DPA1. Each of the third dummy sub-pixels DP_3 can have a third length L_DP-3. The third length L_DP-3 of the third dummy sub-pixel DP_3 can be equal to the first length L_P of the sub-pixel SP positioned at the outermost area of the display area AA. Additionally, the third dummy sub-pixel DP_3 can be the same size as the first dummy sub-pixel DP_1.

The first non-display area NAA1 can include the first gap area GA1 defined between the display area AA and the link line area 300. A portion of the first gap area GA1 can be filled by the plurality of third dummy sub-pixels DP_3 arranged on the third dummy pixel area B_DPA1. The plurality of third dummy sub-pixels DP_3 can be arranged in a multi-stage structure outward of the sub-pixels SP arranged at the outermost area of the display area AA. The third dummy sub-pixel DP_3 can be one of the barrier structures of the first size. In addition, the third dummy sub-pixel DP_3 can be referred to as a third barrier structure.

The third dummy sub-pixel DP_3 can include a configuration in which the third metal pattern 225 for trapping hydrogen is disposed to overlap the second semiconductor layer 241. The configuration of the third dummy sub-pixel DP_3 can be the same as that of the first dummy sub-pixel DP_1 shown in FIG. 8.

The plurality of dummy sub-pixels as the barrier structures can be arranged at the bezel area surrounding the outer side of the display area AA to block hydrogen from being introduced into the driving transistor on the display area AA from the outside of the display panel 200. For example, the plurality of dummy sub-pixels can be arranged at an entire area of the bezel area.

The display panel 200 applied to the wearable display device 100 such as the smart watch phone can have a very narrow bezel area. In an embodiment of the present disclosure, the dummy sub-pixels DP_1, DP_2, and DP_3 can be arranged at the first gap area GA1 on the bezel area, thereby minimizing portions of the bezel area at upper, left, and right side portions of the display panel 200.

In one example, a portion of the bezel area at the lower portion of the display panel 200 can be relatively narrower than the portions of the bezel area at the upper, left, and the right portions of the display panel 200.

According to an embodiment of the present disclosure, a structure in the area 'IV', which is the second corner of the display panel 200, can also be present in the third corner of the display panel 200. In this light, the third dummy sub-pixels DP_3 can be arranged in the X-axis direction from the display area AA to the link line area 300 in rows or arranged in the Y-axis direction from the display area AA to the link line area 300 in columns, so one or more first dummy sub-pixel DP_1 can separate the sub-pixel SP disposed at the outermost area of the display area AA and the link line area 300, for each row or column of the third dummy sub-pixels DP_3. In embodiments of the present disclosure, the number of third dummy sub-pixels DP_3 in the third dummy pixel area B_DPA1 can be the same or different from row to row or column to column. In the third dummy pixel area B_DPA1, a step structure can be formed between adjacent rows or columns of the third dummy sub-pixels DP_3.

In an embodiment of the present disclosure, the plurality of dummy sub-pixels, which are the barrier structures that prevent the hydrogen penetration, can also be arranged at the portion of the bezel area at the lower portion of the display panel 200, which is relatively narrower.

Referring to FIG. 11, the plurality of sub-pixels SP can be arranged on the display area AA. The plurality of sub-pixels SP can be the sub-pixels SP arranged at the outermost area of the display area AA. Each sub-pixel SP can have the first length L_P. One sub-pixel SP disposed on the display area AA can include the same components as those of the sub-pixel in FIG. 3. For example, the second transistor 240, which is the driving transistor, can include the second semiconductor layer 241, which is the oxide semiconductor.

The first non-display area NAA1 can be defined outward of the display area AA. The first non-display area NAA1 can also be referred to as the bezel area. The first non-display area NAA1 can include a second gap area GA2 defined between the display area AA and the bendable area BDA. The second gap area GA2 can be smaller than the first gap area GA1 disposed at the upper, left, and right side portions of the display panel 200. The second gap area GA2 can include the third dummy pixel area B_DPA1 and a fourth dummy pixel area B_DPA2. The third dummy pixel area B_DPA1 can be defined in the portion of the bezel area at the lower portion of the display panel 200. For example, the lower portion of the bezel area can be located between the display area AA and the bendable area BDA.

The third dummy pixel area B_DPA1 can be located between the display area AA and the bendable area BDA. For example, the third dummy pixel area B_DPA1 can be an area extending from the bezel area at the lower corner of the display panel 200 in FIG. 10. The fourth dummy pixel area B_DPA2 can be located between the third dummy pixel area B_DPA1 and the bendable area BDA. For example, the fourth dummy pixel area B_DPA2 can have a smaller area size than the third dummy pixel area B_DPA1.

The plurality of third dummy sub-pixels DP_3 can be located on the third dummy pixel area B_DPA1. Each third dummy sub-pixels DP_3 can have the third length L_DP-3. The third length L_DP-3 of the third dummy sub-pixel DP_3 can be equal to the first length L_P of the sub-pixel SP disposed on the display area AA. The third dummy sub-pixel DP_3 can be one of the barrier structures of the first size. In addition, the third dummy sub-pixel DP_3 can be referred to as the third barrier structure.

A plurality of fourth dummy sub-pixels DP_4 can be arranged on the fourth dummy pixel area B_DPA2. Each of the fourth dummy sub-pixels DP_4 can have a fourth length L_DP-4. The fourth dummy sub-pixel DP_4 can be one of barrier structures of a second size. In addition, the fourth dummy sub-pixel DP_4 can be referred to as a fourth barrier structure. The fourth length L_DP-4 of the fourth dummy sub-pixel DP_4 can be smaller than the third length L_DP-1 of the third dummy sub-pixel DP_3. The fourth dummy sub-pixels DP_4 can be smaller than the first dummy sub-pixels DP_1 or the second dummy sub-pixels DP_2 disposed at the upper, left, and right side portions of the display panel 200.

Accordingly, the third dummy sub-pixels DP_3 having the same size as the sub-pixels SP are arranged on the narrow lower portion of the bezel area, and then the fourth dummy sub-pixels DP_4 having a size smaller than the third dummy sub-pixels DP_3 are arranged even when only a small space remains, thereby allowing the multiple dummy sub-pixels to be arranged on the lower portion of the bezel area. In addition, the third dummy sub-pixels DP_3 and the fourth dummy sub-pixels DP_4 having the different sizes can be arranged in the second gap area GA2, which is smaller than the first gap area GA1. Accordingly, because no additional area is required for arranging the dummy sub-pixels, the bezel area can be minimized.

The fourth dummy sub-pixel DP_4 can be smaller than the other dummy sub-pixels, while the third metal pattern 225 including the transition metal material having the hydrogen capture effect can increase a pattern density ratio in the fourth dummy sub-pixel DP_4. For example, the pattern density ratio of the third metal pattern 225 in the fourth dummy sub-pixel DP_4, which is smaller than other dummy sub-pixels, can be at least 30% of that of the display area AA. For example, the pattern density ratio of the third metal pattern 225 can be 31% of that of the display area AA. A dummy sub-pixel smaller in size than the fourth dummy sub-pixel DP_4 can be constructed. In this case, a pattern density ratio of the third metal pattern 225 in the dummy sub-pixel smaller in size than the fourth dummy sub-pixel DP_4 can be at least 20% of the display area AA. For example, the pattern density ratio of the third metal pattern 225 can be 24% of that of the display area AA. Pattern density ratios of the third metal pattern 225 in the first to third sub-pixels DP_1, DP_2, and DP_3, which are relatively greater in size than the fourth dummy sub-pixel DP_4, can be equal to or smaller than 9% of that of the display area AA. Accordingly, the pattern density ratio of the third metal pattern 225 in the fourth dummy sub-pixel DP_4 is relatively higher than those in other dummy sub-pixels. When the pattern density ratio of the third metal pattern 225 in the dummy sub-pixel is great, hydrogen introduced from the outside can be more blocked for the same area size.

Accordingly, because the multiple dummy sub-pixels having the different sizes are arranged on the narrow bezel area and block hydrogen introduced from the outside, element characteristics of the oxide thin-film transistor can be prevented from being deteriorated or changed.

Therefore, the occurrence of the bright dot defect at the outer portion of the display panel 200 caused by a deterioration or a change in element characteristics of the driving transistor can be prevented. Accordingly, a defect rate of the display device resulted from the bright dot defect or the like can be reduced, and thus production energy required for additional production of the display device can be reduced, which can reduce greenhouse gas emission.

Referring to FIGS. 11 and 12 together, the fourth dummy sub-pixel DP_4 disposed on the fourth dummy pixel area B_DPA2 can have the lower interlayer insulating structure 207 and the third buffer layer 212 disposed on the substrate 201. The first semiconductor layer 221 can be disposed on the third buffer layer 212. The first semiconductor layer 221 can be made of the same material as and formed in the same process as the first semiconductor layer 221 of the sub-pixel SP of the display area AA and the second dummy sub-pixel DP_2. For example, the first semiconductor layer 221 can be made of one of a polysilicon semiconductor layer and a low-temperature polysilicon semiconductor layer, or a combination thereof.

The first semiconductor layer 221 can be connected to one of the first source/drain electrodes 224. The fourth dummy sub-pixel DP_4 can be formed with a smaller area size than the first dummy sub-pixel DP_1 and the second dummy sub-pixel DP_2. Accordingly, unlike in the first dummy sub-pixel DP_1 and the second dummy sub-pixel DP_2, only the first semiconductor layer 221 and the first source/drain electrodes 224 among the components of the first transistor can be disposed in the fourth dummy sub-pixel DP_4.

The second transistor 240 and the storage capacitor 230 can be arranged at different locations spaced apart from the first semiconductor layer 221 and the first source/drain electrodes 224. The second transistor 240 can include the second semiconductor layer 241, the second gate insulating layer 242, the second gate electrode 243, and the second source/drain electrodes 245. The second semiconductor layer 241 of the second transistor 240 can be formed as the oxide semiconductor layer. For example, the second semiconductor layer 241 can include at least one of oxide semiconductor materials such as indium gallium zinc oxide (IGZO) or indium zinc oxide (IZO).

The upper interlayer structure 218 and 219 including the fourth interlayer insulating layer 218 and the fifth interlayer insulating layer 219 can be disposed on the second gate electrode 243 of the second transistor 240.

A partial pattern of the first source/drain electrodes 224 and the second source/drain electrodes 245 can be disposed on the fifth interlayer insulating layer 219. The partial pattern of the first source/drain electrodes 224 can be connected to the source/drain areas of the first semiconductor layer 221 by extending through the insulating layers disposed thereunder. The second source/drain electrodes 245 can be in direct contact with and connected to the source/drain areas of the second semiconductor layer 241 by extending through the upper interlayer structures 218 and 219, respectively. A portion of the second source/drain electrodes 245 of the second transistor 240 can be in direct contact with the third metal pattern 225 by extending through the insulating layers disposed thereunder.

The storage capacitor 230 can include the first storage electrode 231 and the second storage electrode 233 overlapping each other in the vertical direction with the fourth interlayer insulating layer 218 of the upper interlayer structure 218 and 219 disposed therebetween.

The passivation layer 247 including the inorganic insulating material can cover a portion of the first source/drain electrodes 224 and the second source/drain electrodes 245.

The first planarization layer 250 can be disposed on the passivation layer 247. The pixel contact electrode 255 can be disposed on the first planarization layer 251. The pixel contact electrode 255 can be disposed above the second transistor 240.

In the fourth dummy sub-pixel DP_4, the pixel contact electrode 255 is electrically connected to the pixel contact electrode 255 of the display area AA, and thus is able to be electrically connected to the high-potential power supply (VDD) line. For example, the high-potential power supply (VDD) line can be disposed on the link line area 300 of the first non-display area NAA1.

The second planarization layer 252 can be disposed on the first planarization layer 251 and the pixel contact electrode 255. The pixel contact electrode 255 of the fourth dummy sub-pixel DP_4 is covered by the second planarization layer 252. Accordingly, the second transistor 240 of the fourth dummy sub-pixel DP_4 can be the dummy transistor that does not function as the driving transistor.

The planarization layer 250 can be composed of the first planarization layer 251 and the second planarization layer 252. The planarization layer 250 can flatten a step caused by the lower circuit structure.

The organic insulating structure 262a can be disposed on the planarization layer 250. The organic insulating structure 262a can be made of the same material as the bank 262 and formed in the same process as the bank 262 on the display area AA. The organic insulating structure 262a can cover the entire surface of the second planarization layer 252 in the fourth dummy sub-pixel DP_4.

In the fourth dummy sub-pixel DP_4, the second semiconductor layer 241 of the second transistor 240 can be disposed to overlap the third metal pattern 225 in the vertical direction. Because the third metal pattern 225 includes the transition metal material capable of capturing hydrogen, hydrogen can be prevented from being introduced into the second semiconductor layer 241 including the oxide semiconductor material. For example, the third metal pattern 225 can include titanium (Ti). The third metal pattern 225 can be formed to have the size greater than the width of the second semiconductor layer 241 to prevent the second semiconductor layer 241 from being exposed to hydrogen.

The plurality of fourth dummy sub-pixels DP_4 are arranged outward of the third dummy sub-pixels DP_3, so that the hydrogen inflow can also be blocked in each fourth dummy sub-pixel DP_4. Accordingly, barrier structures composed of a multi-stage structure of the plurality of third dummy sub-pixel DP_3 and the fourth dummy sub-pixels DP_4 can be arranged on the lower portion of the bezel area of the display panel 200. Therefore, the barrier structures composed of the multi-stage structure can prevent hydrogen from being introduced into the sub-pixels SP on the display area AA from outside of a lower distal end of the display panel 200. Accordingly, the deterioration or the change in the element characteristics of the driving transistor including the oxide semiconductor on the display area AA can be prevented, so that operational stability of the display device can be improved. In addition, because the multiple dummy sub-pixels with the different sizes are arranged on the narrow bezel area, no additional space is required, so that the bezel area can be minimized.

According to an embodiment of the present disclosure, the organic insulating structure 262a can be disposed on the planarization layer 250 as a sheet without any recess thereon in at least one of the third dummy pixel area B_DPA1 and the fourth dummy pixel area B_DPA2. For example, the organic insulating structure 262a does not cover the first electrode 261 in the third dummy pixel area B_DPA1 and the fourth dummy pixel area B_DPA2 since the third dummy pixel area B_DPA1 and the fourth dummy pixel area B_DPA2 can be without the light emitting element 260. Additionally, the third dummy pixel area B_DPA1 and/or the fourth dummy pixel area B_DPA2 can be without the first metal pattern 209a and/or the second metal pattern 223a, and the pixel contact electrode 255 can be not electrically connected to the second transistor 240.

According to an embodiment of the present disclosure, the third metal patterns 225 associated with the first through fourth dummy sub-pixels DP_1 through DP_4 can be arranged to encircle the display area AA at the first non-display area NAA1.

The display device according to various embodiments of the present disclosure can be described as follows.

One aspect of the present disclosure provides a display device comprising: a display panel including a display area and a non-display area surrounding the display area; a plurality of sub-pixels disposed in the display area; a first area included in the non-display area and surrounding three sides of the display area in a plan view of the display device; a second area included in the non-display area and disposed in a position different from a position of the first area; a bendable area included in the non-display area; a first-sized barrier structure disposed in the first area; and a further first-sized barrier structure and a second-sized barrier structure disposed in the second area and spaced apart from each other, wherein the first-sized barrier structure and the second-sized barrier structure have different sizes in the plan view.

In accordance with some embodiment, the second-sized barrier structure is smaller than the first-sized barrier structure.

In accordance with some embodiment, the first area of the non-display area includes a first dummy pixel area in an upper corner of the display panel, and a second dummy pixel area in upper, left, and right side portions of the display panel in the plan view, wherein the second area of the non-display area includes a third dummy pixel area between a portion of the display area in a lower portion of the display panel and the bendable area, and a fourth dummy pixel area between the third dummy pixel area and the bendable area in the plan view, wherein the first-sized barrier structure is disposed in each of the first dummy pixel area and the second dummy pixel area, wherein the further first-sized barrier structure is disposed in the third dummy pixel area, wherein the second-sized barrier structure is disposed in the fourth dummy pixel area.

In accordance with some embodiment, the first-sized barrier structure disposed in the first dummy pixel area includes a first dummy sub-pixel, the first-sized barrier structure disposed in the second dummy pixel area includes a second dummy sub-pixel, the further first-sized barrier structure disposed in the third dummy pixel area includes a third dummy sub-pixel, and the second-sized barrier structure disposed in the fourth dummy pixel area includes a fourth dummy sub-pixel, wherein in the plan view, a size of the fourth dummy sub-pixel is smaller than a size of each of the first dummy sub-pixel, the second dummy sub-pixel, and the third dummy sub-pixel.

In accordance with some embodiment, in the plan view, the first dummy sub-pixel has the same size as a size of the sub-pixel of the display area.

In accordance with some embodiment, in the plan view, the third dummy sub-pixel has the same size as a size of the first dummy sub-pixel.

In accordance with some embodiment, each of the plurality of sub-pixels includes: an oxide thin-film transistor including: a semiconductor layer; a gate insulating layer disposed on the semiconductor layer; a gate electrode disposed on the gate insulating layer; and source/drain electrodes respectively disposed on both opposing sides of the gate electrode and connected to the semiconductor layer; and a light-emitting element electrically connected to the oxide thin-film transistor, wherein the semiconductor layer includes an oxide semiconductor material.

In accordance with some embodiment, each of the plurality of sub-pixels further includes a metal pattern overlapping the oxide thin-film transistor in a vertical direction and including a transition metal material for capturing hydrogen.

In accordance with some embodiment, a width of the metal pattern is greater than a width of the semiconductor layer of the oxide thin-film transistor.

In accordance with some embodiment, the oxide semiconductor material includes indium gallium zinc oxide or indium zinc oxide, and the transition metal material includes titanium.

In accordance with some embodiment, the first dummy sub-pixel includes: an oxide thin-film transistor including: a semiconductor layer including an oxide semiconductor material; a gate electrode disposed to be spaced apart from the semiconductor layer; and source/drain electrodes respectively disposed on both opposing sides of the gate electrode; a planarization layer disposed on the oxide thin-film transistor; an organic insulating structure covering the planarization layer; and a metal pattern overlapping the oxide thin-film transistor in a vertical direction and including a transition metal material for capturing hydrogen, wherein a width of the metal pattern is greater than a width of the semiconductor layer of the oxide thin-film transistor.

In accordance with some embodiment, the fourth dummy sub-pixel includes: an oxide thin-film transistor disposed on a substrate at one side thereof, and including a semiconductor layer including an oxide semiconductor material, a gate electrode, and source/drain electrodes; a first planarization layer disposed on the oxide thin-film transistor; a second planarization layer disposed on the first planarization layer; an organic insulating structure covering the second planarization layer; and a pixel contact electrode disposed on the first planarization layer and vertically overlapping and spaced upwardly from the source/drain electrodes.

In accordance with some embodiment, the fourth dummy sub-pixel further includes a metal pattern overlapping the oxide thin-film transistor in a vertical direction and including a transition metal material for capturing hydrogen, wherein a width of the metal pattern is greater than a width of the semiconductor layer of the oxide thin-film transistor.

In accordance with some embodiment, the pixel contact electrode of the fourth dummy sub-pixel is electrically connected to a pixel contact electrode of the display area and electrically connected to a high-potential power line.

Although some embodiments of the present disclosure have been described above with reference to the accompanying drawings, the present disclosure need not be limited to some embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some embodiments as described above are not restrictive but illustrative in all respects.

What is claimed is:

1. A display device comprising:
a display panel including a display area and a non-display area adjacent to the display area;
a plurality of sub-pixels disposed in the display area;
a first area included in the non-display area and adjacent to at least one of three sides of the display area in a plan view of the display device;
a second area included in the non-display area and disposed in a position different from a position of the first area;
a bendable area included in the non-display area;
a first-sized barrier structure disposed in the first area; and
a further first-sized barrier structure and a second-sized barrier structure disposed in the second area and spaced apart from each other,
wherein the first-sized barrier structure and the second-sized barrier structure have different sizes in the plan view of the display device.

2. The display device of claim 1, wherein the second-sized barrier structure is smaller in size than the first-sized barrier structure.

3. The display device of claim 1, wherein the first area of the non-display area includes a first dummy pixel area in at least an upper corner of the display panel, and a second dummy pixel area in upper, left, and right side portions of the display panel in the plan view of the display device,
wherein the second area of the non-display area includes a third dummy pixel area between a portion of the display area in a lower portion of the display panel and the bendable area, and a fourth dummy pixel area between the third dummy pixel area and the bendable area in the plan view of the display device,
wherein the first-sized barrier structure is disposed in each of the first dummy pixel area and the second dummy pixel area,
wherein the further first-sized barrier structure is disposed in the third dummy pixel area, and
wherein the second-sized barrier structure is disposed in the fourth dummy pixel area.

4. The display device of claim 3, wherein the first-sized barrier structure disposed in the first dummy pixel area includes a first dummy sub-pixel, the first-sized barrier structure disposed in the second dummy pixel area includes a second dummy sub-pixel, the further first-sized barrier structure disposed in the third dummy pixel area includes a third dummy sub-pixel, and the second-sized barrier structure disposed in the fourth dummy pixel area includes a fourth dummy sub-pixel, and
wherein in the plan view of the display device, a size of the fourth dummy sub-pixel is smaller than a size of each of the first dummy sub-pixel, the second dummy sub-pixel, and the third dummy sub-pixel.

5. The display device of claim 4, wherein in the plan view of the display device, the first dummy sub-pixel has a same size as a size of the sub-pixel of the display area.

6. The display device of claim 4, wherein in the plan view of the display device, the third dummy sub-pixel has a same size as a size of the first dummy sub-pixel.

7. The display device of claim 1, wherein each of the plurality of sub-pixels includes:
an oxide thin-film transistor including:
a semiconductor layer;
a gate insulating layer disposed on the semiconductor layer;
a gate electrode disposed on the gate insulating layer; and
source and drain electrodes respectively disposed on both opposing sides of the gate electrode and connected to the semiconductor layer; and
a light-emitting element electrically connected to the oxide thin-film transistor, and
wherein the semiconductor layer includes an oxide semiconductor material.

8. The display device of claim 7, wherein each of the plurality of sub-pixels further includes a metal pattern overlapping the oxide thin-film transistor in a vertical direction and including a transition metal material for capturing hydrogen in the display device.

9. The display device of claim 8, wherein a width of the metal pattern is greater than a width of the semiconductor layer of the oxide thin-film transistor.

10. The display device of claim 8, wherein the oxide semiconductor material includes indium gallium zinc oxide or indium zinc oxide, and the transition metal material includes titanium.

11. The display device of claim 4, wherein the first dummy sub-pixel includes:
an oxide thin-film transistor including:
a semiconductor layer including an oxide semiconductor material;
a gate electrode disposed to be spaced apart from the semiconductor layer; and
source and drain electrodes respectively disposed on both opposing sides of the gate electrode;
a planarization layer disposed on the oxide thin-film transistor;
an organic insulating structure covering the planarization layer; and
a metal pattern overlapping the oxide thin-film transistor in a vertical direction and including a transition metal material for capturing hydrogen, and
wherein a width of the metal pattern is greater than a width of the semiconductor layer of the oxide thin-film transistor.

12. The display device of claim 4, wherein the fourth dummy sub-pixel includes:
an oxide thin-film transistor disposed on a substrate at one side thereof, and including a semiconductor layer including an oxide semiconductor material, a gate electrode, and source and drain electrodes;
a first planarization layer disposed on the oxide thin-film transistor;
a second planarization layer disposed on the first planarization layer;
an organic insulating structure covering the second planarization layer; and
a pixel contact electrode disposed on the first planarization layer and vertically overlapping and spaced upwardly from the source and drain electrodes.

13. The display device of claim 12, wherein the fourth dummy sub-pixel further includes a metal pattern overlapping the oxide thin-film transistor in a vertical direction and including a transition metal material for capturing hydrogen, and
wherein a width of the metal pattern is greater than a width of the semiconductor layer of the oxide thin-film transistor.

14. The display device of claim 12, wherein the pixel contact electrode of the fourth dummy sub-pixel is electrically connected to a pixel contact electrode of the display area and electrically connected to a power line.

15. A display device comprising:
a display panel including a display area and a non-display area outside the display area;
a plurality of sub-pixels disposed in the display area;
a first area included in the non-display area and adjacent to the display area in a plan view of the display device;
a second area included in the non-display area and disposed in a position different from a position of the first area; and
a bendable area included in the non-display area,
wherein the first area includes an upper portion, a right side portion, a lower portion and a left side portion arranged in a clockwise direction in the plan view of the display device,
wherein each of the upper portion, the right side portion, the lower portion and the left side portion includes a barrier structure including a plurality of metal patterns configured to capture hydrogen from the display device, and
wherein the plurality of metal patterns are located along the first area to surround the display area in the plan view of the display device.

16. The display device of claim 15, wherein the display panel further comprises a first corner, a second corner, a third corner and a fourth corner in the clockwise direction of the display panel in the plan view starting from the upper portion of the first area.

17. The display device of claim 16, wherein the first corner is a transition from the upper portion to the right side portion, the second corner is a transition from the right side portion to the lower portion, the third corner is a transition from the lower portion to the left side portion, and the fourth corner is a transition from the left side portion to the upper portion in the clockwise direction around a periphery of the display panel.

18. The display device of claim 17, wherein the first area of the non-display area includes a first dummy pixel area in at least the first corner of the display panel, and a second dummy pixel area in at least one of the upper portion, the left side portion, and the right side portion of the display panel in the plan view of the display device, and
wherein the second area of the non-display area includes a third dummy pixel area between a portion of the display area in the lower portion of the display panel and the bendable area, and a fourth dummy pixel area between the third dummy pixel area and the bendable area in the plan view of the display device.

19. The display device of claim 18, wherein the first dummy pixel area includes a first dummy sub-pixel, the second dummy pixel area includes a second dummy sub-pixel, the third dummy pixel area includes a third dummy sub-pixel, and the fourth dummy pixel area includes a fourth dummy sub-pixel, and
wherein in the plan view of the display device, a size of the fourth dummy sub-pixel is smaller than a size of each of the first dummy sub-pixel, the second dummy sub-pixel, and the third dummy sub-pixel.

20. The display device of claim 19, wherein in the plan view of the display device, the first dummy sub-pixel has a same size as a size of a sub-pixel of the display area, and the third dummy sub-pixel has a same size as the size of the first dummy sub-pixel.
